(19) United States
(12) Patent Application Publication
(10) Pub. No.: US 2024/0264744 A1
(43) Pub. Date: Aug. 8, 2024

(54) MEMORY CONTROLLER AND MEMORY SYSTEM INCLUDING THE MEMORY CONTROLLER AND MEMORY DEVICE

(71) Applicant: SK hynix Inc., Icheon-si Gyeonggi-do (KR)

(72) Inventor: Se Chang PARK, Icheon-si Gyeonggi-do (KR)

(73) Assignee: SK hynix Inc., Icheon-si Gyeonggi-do (KR)

(21) Appl. No.: 18/364,972

(22) Filed: Aug. 3, 2023

(30) Foreign Application Priority Data
Feb. 7, 2023 (KR) 10-2023-0016226

(51) Int. Cl. G06F 3/06

(52) U.S. Cl. CPC G06F 3/0611; G06F 3/0653; G06F 3/0656; G06F 3/0679

(57) ABSTRACT

A memory system includes a memory device including a plurality of memory blocks and a memory controller. The memory controller determines, when a read request for data stored in a first memory block among the plurality of memory blocks is received, whether a dummy read operation on the first memory block is to be performed, based on an erase count value of a second memory block which shares a block word line with the first memory block before a read operation on the first memory block is performed.

### CROSS-REFERENCE TO RELATED APPLICATION

The present application claims priority under 35 U.S.C. § 119(a) to Korean patent application number 10-2023-0016226 filed on Feb. 7, 2023, in the Korean Intellectual Property Office, the entire disclosure of which is incorporated by reference herein.

### BACKGROUND

### 1. Technical Field

The present disclosure generally relates to an electronic device, and more particularly, to a memory controller and a memory system including the memory controller and a memory device.

### 2. Related Art

A memory system is a device which stores data under the control of a host device such as a computer or a smart phone. The memory system may include a memory device for storing data and a memory controller for controlling the memory device. The memory device is classified as a volatile memory device or a nonvolatile memory device.

A nonvolatile memory device is a memory device in which data does not disappear even when the supply of power is interrupted. The nonvolatile memory device may include a Read-Only Memory (ROM), Programmable ROM (PROM), Electrically Programmable ROM (EPROM), Electrically Erasable ROM (EEROM), flash memory, and the like.

The nonvolatile memory device may include a plurality of memory blocks in which data is stored. Any one memory block among the plurality of memory blocks may share a block word line with another memory block. When an operation on any one memory block is performed, a threshold voltage distribution of memory cells included in another memory block may be changed. When the threshold voltage distribution of the memory cells included in the other memory block is changed, a read operation of reading data stored in the memory cells may fail.

### SUMMARY

Some embodiments are directed to a memory system including a memory controller and a memory device, which can reduce a time required to provide a host with data stored in the memory device.

In accordance with an embodiment of the present disclosure, a memory system includes: a memory device including a plurality of memory blocks; and a memory controller configured to, when a read request for data stored in a first memory block among the plurality of memory blocks is received, determine whether a dummy read operation on the first memory block is to be performed, based on an erase count value of a second memory block which shares a block word line with the first memory block before a read operation on the first memory block is performed.

In accordance with another embodiment of the present disclosure, a method of operating a memory system includes: storing erase count values of respective memory blocks of a plurality of memory blocks; identifying an erase count value of a second memory block which shares a block word line with a first memory block among the plurality of memory blocks in response to a read request of a host with respect to data stored in the first memory block; determining whether a dummy read operation on the first memory block is to be performed, based on the erase count value of the second memory block; and performing a read operation on the first memory block.

In accordance with still another embodiment of the present disclosure, a memory controller includes: a host interface configured to receive a read request for requesting data stored in a selected memory block among a plurality of memory blocks; and an operation controller configured to identify an erase count value of a shared memory block which shares a block word line with the selected memory block among erase count values corresponding to the respective memory blocks of a plurality of memory blocks in response to the read request, and selectively perform a dummy read operation on the selected memory block, based on the erase count value of the shared memory block and then read the data stored in the selected memory block.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be enabling to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating a memory system in accordance with an embodiment of the present disclosure.

FIG. 2 is a diagram illustrating a memory device shown in FIG. 1.

FIG. 3 is a diagram illustrating a shared memory block which shares a block word line with a selected memory block.

FIG. 4 is a diagram illustrating a threshold voltage distribution of memory cells included in a selected memory block, which is changed according to an erase operation on a shared memory block.

FIG. 5 is a diagram illustrating erase count information.

FIG. 6 is a diagram illustrating reference count information.

FIG. 7 is a diagram illustrating a dummy read operation and a read operation of the memory system according to a read request of a host.

FIG. 8 is a flowchart illustrating operation of the memory system in accordance with an embodiment of the present disclosure.

FIG. 9 is a diagram illustrating a memory controller shown in FIG. 1.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and should not be construed as limited to the embodiments set forth herein.

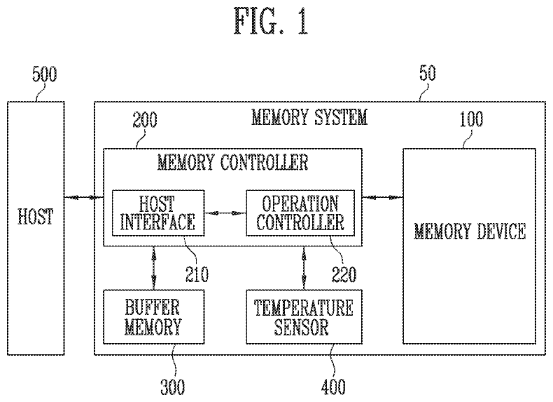

FIG. 1 is a diagram illustrating a memory system in accordance with an embodiment of the present disclosure.

Referring to FIG. 1, the memory system 50 may include a memory device 100, a memory controller 200, a buffer memory 300, and a temperature sensor 400. The memory system 50 may be a device which is included in a mobile phone, a computer, an in-vehicle infotainment, or the like, and stores data under the control of a host 500 as an external device.

The memory system 50 may be manufactured as any one of various types of storage devices such as a Solid State Drive (SSD) and a Universal Flash Storage according to a host interface as a communication scheme with the host 500. The memory system 50 may be manufactured as any one of various kinds of package types, such as a System-On-Chip (SOC).

The memory device 100 may store data. The memory device 100 may be operated under the control of the memory controller 200. In an embodiment, the memory device 100 may be a volatile memory device or a nonvolatile memory device.

The memory device 100 may receive a command and an address from the memory controller 200, and access an area selected by the address. The memory device 100 may perform an operation instructed by the command on the area selected by the address. The memory device 100 may perform a program operation (write operation) of storing data in the area selected by the address, a read operation of reading data, or an erase operation of erasing data.

The memory controller 200 may control overall operations of the memory system 50.

When power is applied to the memory system 50, the memory controller 200 may execute firmware (FW). In an embodiment, the memory controller 200 may control communication between the host 500 and the memory device 100 by executing the FW. In an embodiment, the memory controller 200 may translate a logical address of the host 500 into a physical address of the memory device 100.

The memory controller 200 may control the memory device 100 to perform a program operation, a read operation, an erase operation, or the like in response to a request from the host 500. The memory controller 200 may provide the memory device 100 with a command, a physical address, or data according to the program operation, the read operation, or the erase operation.

In an embodiment, the memory controller 200 may autonomously generate a command, an address, and data, regardless of any request from the host 500, and transmit the command, the address, and the data to the memory device 100. For example, the memory controller 200 may provide the memory device 100 with a command, an address, and data, which are used to perform read and program operations accompanied in performing wear leveling, read reclaim, garbage collection, and the like.

In an embodiment, the memory controller 200 may control at least two memory devices 100. The memory controller 200 may control the memory devices according to an interleaving scheme so as to improve operational performance. The interleaving scheme may be a scheme for controlling operations on at least two memory devices 100 to overlap with each other.

The buffer memory 300 may temporarily store data provided from the host 500 or temporarily store data read from the memory device 100. In an embodiment, the buffer memory 300 may be a volatile memory device. For example, the buffer memory 300 may be a Dynamic Random-Access Memory (DRAM) or a Static Random-Access Memory (SRAM). In an embodiment, the buffer memory 300 may be located at the outside of the memory controller 200 or be located at the inside of the memory controller 200.

In an embodiment, the buffer memory 300 may store meta data. The meta data may be data including information used for operation of the memory system 50. In an embodiment, the meta data may include map data representing a corresponding relation between a logical address of the host 500 and a physical address of the memory device 100.

In an embodiment, the buffer memory 300 may store erase count information read from the memory device 100. The erase count information may be information on a number of times an erase operation on each of a plurality of memory blocks included in the memory device 100 is performed. The erase count information may include erase count values of the respective plurality of memory blocks. The erase count values may be updated by the memory controller 200, based on the number of times the erase operation on each of the plurality of memory blocks is performed.

In an embodiment, the buffer memory 300 may store reference count information read from the memory device 100. The reference count information may include reference count values to be compared with the erase count values. The reference count values may be count values which become a reference for determining whether a dummy read operation on a selected memory block among the plurality of memory blocks is to be performed. The reference count values may have different values, based on temperature information. In an embodiment, a reference count value corresponding to high temperature information representing a high temperature may be a greatest value among the reference count values. In an embodiment, a reference count value corresponding to low temperature information representing a low temperature may be a smallest value among the reference count values.

The temperature sensor 400 may measure a temperature of the memory system 50. The temperature sensor 400 may generate temperature information, based on the temperature of the memory system 50. The temperature sensor 400 may generate temperature information corresponding to any one of low, mid, and high temperature information, based on the temperature of the memory system 50. In an embodiment, the temperature sensor 400 may provide the temperature information to the memory controller 200 in response to a control signal of the memory controller 200. In an embodiment, the temperature sensor 400 may periodically provide the temperature to the memory controller 200. In an embodiment, the temperature sensor 400 may be located at the inside of the memory controller 200.

In an embodiment, the memory controller 200 may include a host interface 210 and an operation controller 220.

The host interface 210 may receive a request of the host 500. In an embodiment, the host interface 210 may provide the operation controller 220 with a write request and data, which are received from the host 500. In an embodiment, the host interface 210 may provide the operation controller 220 with a read request received from the host 500.

The operation controller 220 may control an operation of the memory system 50. The operation controller 220 may control a program operation of storing the received data in the memory device 100 according to the write request of the host 500. The operation controller 220 may control a read operation of reading data stored in the memory device 100 in response to the read request of the host 500.

In an embodiment, the operation controller 220 may determine whether a dummy read operation on the memory device 100 is to be performed, based on the erase count information stored in the buffer memory 300, before the read operation on the memory device 100 is performed in response to the read request of the host 500. For example, in the read request of the host 500, the operation controller 220 may perform the dummy read operation on the memory device 100, based on the erase count information, and then perform the read operation. In another example, in the read request of the host 500, the operation controller 200 does not perform the dummy read operation, based on the erase count information, but may perform the read operation on the memory device 100.

Specifically, the operation controller 220 may identify an erase count value of a shared memory block which shares a block word line with a selected memory block in which data corresponding to the read request of the host 500 is stored among the plurality of memory blocks in response to the read request. The operation controller 220 may acquire, from the buffer memory 300, the erase count value of the shared memory block among erase count values of the respective plurality of memory blocks. The operation controller 220 may acquire a reference count value corresponding to the temperature information received from the temperature sensor 400 among the reference count values.

The operation controller 220 may determine whether a dummy read operation of the selected memory block is to be performed, based on a result obtained by comparing the erase count value of the shared memory block with the reference count value. The operation controller 220 may perform the dummy read operation on the selected memory block, based on a comparison result, and then perform a read operation, or skip the dummy read operation on the selected memory block and perform the read operation. After that, the operation controller 220 may read the data stored in the selected memory block and then provide the read data to the host 500 through the host interface 210.

The host 500 may communicate with the memory system 50 by using various communication schemes.

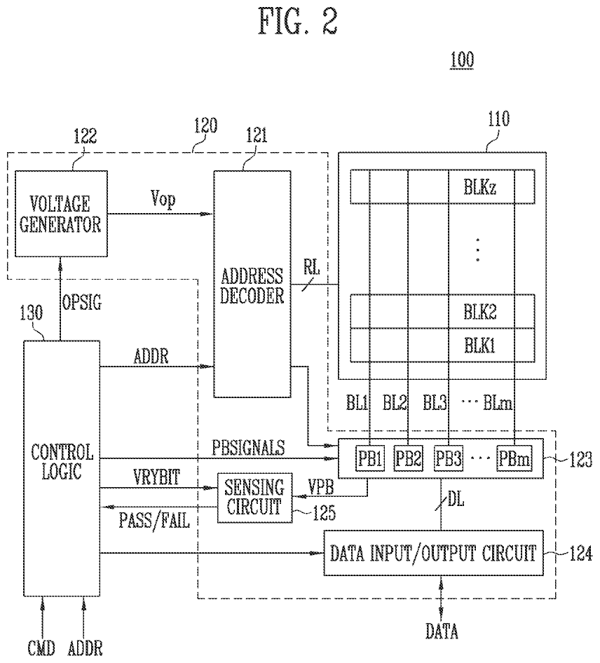

FIG. 2 is a diagram illustrating the memory device shown in FIG. 1.

Referring to FIG. 2, the memory device 100 may include a memory cell array 110, a peripheral circuit 120, and control logic 130.

The memory cell array 110 may include a plurality of memory blocks BLK1 to BLKz. The plurality of memory blocks BLK1 to BLKz may be connected to an address decoder 121 through row lines RL. The plurality of memory blocks BLK1 to BLKz may be connected to a page buffer group 123 through bit lines BL1 to BLm. Each of the plurality of memory blocks BLK1 to BLKz may include a plurality of memory cells. Memory cells connected to the same word line among the plurality of memory cells may be defined as one physical page. In an embodiment, a physical page may be a unit for storing data or reading stored data. One physical page may include a plurality of logical pages. A memory block may be a unit for erasing data.

Each of the memory cells of the memory device 100 may be configured as a Single-Level Cell (SLC) storing one-bit data, a Multi-Level Cell (MLC) storing two-bit data, a Triple-Level Cell (TLC) storing three-bit data, a Quad-Level Cell (QLC) storing four-bit data, or a memory cell storing five-or-more-bit data.

The peripheral circuit 120 may drive the memory cell array 110. For example, the peripheral circuit 120 may drive the memory cell array 110 to perform a program operation, a read operation, and an erase operation under the control of the control logic 130. In another example, the peripheral circuit 120 may apply various operating voltages to the row lines RL and the bit lines BL1 to BLm or discharge the applied voltages under the control of the control logic 130.

The peripheral circuit 120 may include the address decoder 121, a voltage generator 122, the page buffer group 123, a data input/output circuit 124, and a sensing circuit 125.

The address decoder 121 may be connected to the memory cell array 110 through the row lines RL. The row lines RL may include drain select lines, word lines, source select lines, and a source line.

The address decoder 121 may be operated under the control of the control logic 130. The address decoder 121 may receive an address ADDR from the control logic 130.

The address decoder 121 may decode a block address in the received address ADDR. The address decoder 121 may select at least one memory block among the memory blocks BLK1 to BLKz according to the decoded block address. The address decoder 121 may decode a row address in the received address ADDR. The address decoder 121 may select at least one word line WL of the selected memory block by applying voltages provided from the voltage generator 122 to the at least one word line WL according to the decoded row address.

In a program operation, the address decoder 121 may apply a program voltage to the selected word line, and apply a pass voltage having a level lower than a level of the program voltage to unselected word lines. In a program verify operation, the address decoder 121 may apply a verify voltage to the selected word line, and apply a verify pass voltage having a level higher than a level of the verify voltage to the unselected word lines.

In a read operation, the address decoder 121 may apply a read voltage to the selected word line, and apply a read pass voltage having a level higher than a level of the read voltage to the unselected word lines.

The address decoder 121 may decode a column address in the received address ADDR. The decoded column address may be transferred to the page buffer group 123. For example, the address decoder 121 may include components such as a row decoder, a column decoder, and an address buffer.

The voltage generator 122 may generate a plurality of operating voltages Vop by using an external power voltage supplied to the memory device 100. The voltage generator 122 may be operated under the control of the control logic 130.

In an embodiment, the voltage generator 122 may generate various operating voltages Vop used for program, read, and erase operations in response to an operation signal OPSIG. For example, the voltage generator 122 may generate a plurality of erase voltages, a plurality of program voltages, a plurality of pass voltages, a plurality of select read voltages, and a plurality of unselect read voltages. The plurality of operating voltages Vop may be supplied to the memory cell array 110 by the address decoder 121.

The page buffer group 123 may include first to mth page buffers PB1 to PBm. The first to mth page buffers PB1 to PBm may be connected to the memory cell array 110 respectively through first to mth bit lines BL1 to BLm. The first to mth page buffers PB1 to PBm may be operated under the control of the control logic 130.

The first to mth page buffers PB1 to PBm may communicate data DATA with the data input/output circuit 124. In a program operation, the first to mth page buffers PB1 to PBm may receive data DATA to be stored through the data input/output circuit 124 and data lines DL.

In a program operation, the first to mth page buffers PB1 to PBm may transfer data DATA received through the data input/output circuit 124 to selected memory cells through the bit lines BL1 to BLm. The selected memory cells may be programmed according to the transferred data DATA. A memory cell connected to a bit line through which a program allow voltage (e.g., a ground voltage) is applied may have an increased threshold voltage. A threshold voltage of a memory cell connected to a bit line through which a program inhibit voltage (e.g., a power voltage) is applied may be maintained. In a verify operation, the first to mth page buffers PB1 to PBm may read data DATA stored in the selected memory cells from the selected memory cells through the bit lines BL1 to BLm.

In a read operation, the page buffer group 123 may read data DATA from memory cells of a selected page through the bit lines BL, and store the read data DATA in the first to mth page buffers PB1 to PBm.

The data input/output circuit 124 may be connected to the first to mth page buffers PB1 to PBm through the data lines DL. The data input/output circuit 124 may be operated under the control of the control logic 130.

The data input/output circuit 124 may include a plurality of input/output buffers (not shown) which receive input data DATA. In a program operation, the data input/output circuit 124 may receive data DATA to be stored from the memory controller 200. In a read operation, the data input/output circuit 124 may output, to the memory controller 200, data DATA transferred from the first to mth page buffers PB1 to PBm included in the page buffer group 123.

In a read operation or verify operation, the sensing circuit 125 may generate a reference current in response to an allow bit VRYBIT generated by the control logic 130, and output a pass or fail signal PASS/FAIL to the control logic 130 by comparing a sensing voltage VPB received from the page buffer group 123 with a reference voltage generated by the reference current. For example, the sensing circuit 125 may output the pass signal to the control logic 130 when a magnitude of the sensing voltage VPB is smaller than a magnitude of the reference voltage. In another example, the sensing circuit 125 may output the fail signal to the control logic 130 when the magnitude of the sensing voltage VPB is greater than the magnitude of the reference voltage.

The control logic 130 may be connected to the address decoder 121, the voltage generator 122, the page buffer group 123, the data input/output circuit 124, and the sensing circuit 125. The control logic 130 may control a general operation of the memory device 100. The control logic 130 may be operated in response to a command CMD transferred from the memory controller 200. The control logic 130 may be implemented as hardware, software, or a combination of hardware and software. For example, the control logic 130 may be a control logic circuit operating in accordance with an algorithm and/or a processor executing control logic code.

The control logic 130 may control the peripheral circuit 120 by generating several signals in response to a command CMD and an address ADDR. For example, the control logic 130 may generate the operation signal OPSIG, the address ADDR, a page buffer control signal PBSIG, and the allow bit VRYBIT in response to the command CMD and the address ADDR. The control logic 130 may output the operation signal OPSIG to the voltage generator 122, output the address ADDR to the address decoder 121, output the page buffer control signal PBSIG to the page buffer group 123, and output the allow bit VRYBIT to the sensing circuit 125. Also, the control logic 130 may determine whether the verify operation has passed or failed in response to the pass or fail signal PASS/FAIL output by the sensing circuit 125.

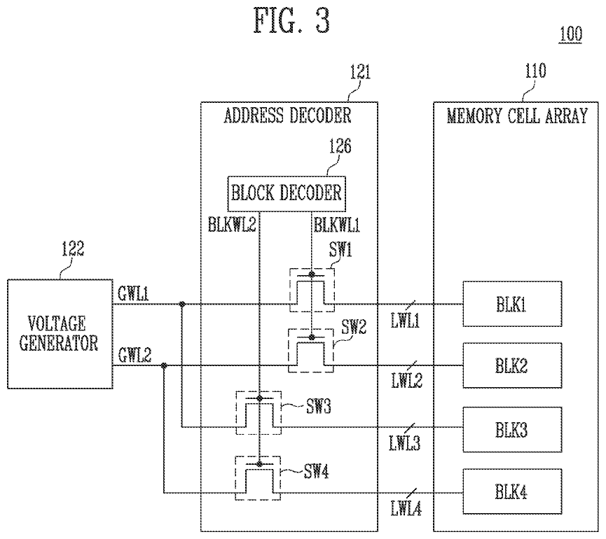

FIG. 3 is a diagram illustrating a shared memory block which shares a block word line with a selected memory block.

In FIG. 3, only the voltage generator 122, the address decoder 121, and the memory cell array 110 are among the components included in the memory device 100 shown in FIG. 2. In an embodiment, the memory cell array 110 may include first to fourth memory blocks BLK1 to BLK4.

Referring to FIGS. 2 and 3, the voltage generator 122 may be connected to the address decoder 121 through global word line groups GWL1 and GWL2. The address decoder 121 may be connected to the memory cell array 110 through local word line groups LWL1 to LWL4.

The voltage generator 122 may generate operating voltages in response to an operation signal received from the control logic. The voltage generator 122 may provide the operating voltages to a first global word line group GWL1 and a second global word line group GWL2.

The address decoder 121 may include a block decoder 126 and first to fourth switch circuits SW1 to SW4. The block decoder 126 may decode a block address in an address received from the control logic. The block decoder 126 may select at least one memory block among the first to fourth memory blocks BLK1 to BLK4, based on the block address. The block decoder 126 may generate a block select signal for selecting at least one memory block. In an embodiment, the block decoder 126 may provide the block select signal to a first block word line BLKWL1, thereby selecting the first memory block BLK1 or the second memory block BLK2. In an embodiment, the block decoder 126 may provide the block select signal to a second block word line BLKWL2, thereby selecting the third memory block BLK3 or the fourth memory block BLK4.

The first to fourth switch circuits SW1 to SW4 may be connected between the first and second global word line groups GWL1 and GWL2 and first to fourth local word line groups LWL1 to LWL4. The first and second switch circuits SW1 and SW2 may be commonly connected to the first block word line BLKWL1. The third and fourth switch circuits SW3 and SW4 may be commonly connected to the second block word line BLKWL2.

The first to fourth switch circuits SW1 to SW4 may electrically connect the first and second global word line groups GWL1 and GWL2 and the first to fourth local word line groups LWL1 to LWL4 to each other or block the connection between the first and second global word line groups GWL1 and GWL2 and the first to fourth local word line groups LWL1 to LWL4, according to the block select signal. In an embodiment, the first and second switch circuits SW1 and SW2 may be turned on when the activated block select signal is applied to the first block word line BLKWL1. When the first and second switch circuits SW1 and SW2 are turned on, the first global word line group GWL1 and the first local word line group LWL1 may be connected to each other, and the second global word line group GWL2 and the second local word line group LWL2 may be connected to each other. In an embodiment, the first and second switch circuits SW1 and SW2 may be turned off when the inactivated block select signal is applied to the first block word line BLKWL1. When the first and second switch circuits SW1 and SW2 are turned on, the connection between the first global word line group GWL1 and the first local word line group LWL1 and the connection between the second global word line group GWL2 and the second local word line group LWL2 may be blocked.

In an embodiment, the third and fourth switch circuits SW3 and SW4 may be turned on when the activated block select signal is applied to the second block word line BLKWL2. When the third and fourth switch circuits SW3 and SW4 are turned on, the first global word line group GWL1 and the third local word line group LWL3 may be connected to each other, and the second global word line group GWL2 and the fourth local word line group LWL4 may be connected to each other. In an embodiment, the third and fourth switch circuits SW3 and SW4 may be turned off when the inactivated block select signal is applied to the second block word line BLKWL2. When the third and fourth switch circuits SW3 and SW4 are turned off, the connection between the first global word line group GWL1 and the third local word line group LWL3 and the connection between the second global word line group GWL2 and the fourth local word line group LWL4 may be blocked.

The first memory block BLK1 and the second memory block BLK2 may share the first block word line BLKWL1 to which the first and second switch circuits SW1 and SW2 are commonly connected. The third memory block BLK3 and the fourth memory block BLK4 may share the second block word line BLKWL2 to which the third and fourth switch circuits SW3 and SW4 are commonly connected.

In an embodiment, a memory block in which data corresponding to a read command input from the memory controller is stored among the plurality of memory blocks may be a selected memory block. Hereinafter, an operation of the memory device when the selected memory block is the first memory block BLK1 will be described.

In an embodiment, the voltage generator 122 may apply operating voltages to the first global word line group GWL1. The voltage generator 122 might not apply the operating voltages to the second global word line group GWL2.

The block decoder 126 may apply the activated block select signal to the first block word line BLKWL1. Because the first block word line BLKWL1 is commonly connected to the first and second switch circuits SW1 and SW2, the first global word line group GWL1 and the first local word line group LWL1 may be connected to each other, and besides, the second global word line group GWL2 and the second local word line group LWL2 may be connected to each other.

The block decoder 126 may apply the inactivated block select signal to the second block word line BLKWL2. The connection between the first global word line group GWL1 and the third local word line group LWL3 and the connection between the second global word line group GWL2 and the fourth local word line group LWL4 may be blocked.

In an embodiment, when the first memory block BLK1 is the selected memory block, the second memory block BLK2 which shares the first block word line BLKWL1 with the first memory block BLK1 may be a shared memory block. Because the inactivated block select signal is applied to the second block word line BLKWL2 when the first memory block BLK1 is the selected memory block, the third memory block BLK3 and the fourth memory block BLK4, which share the second block word line BLKWL2, may be unselected memory blocks.

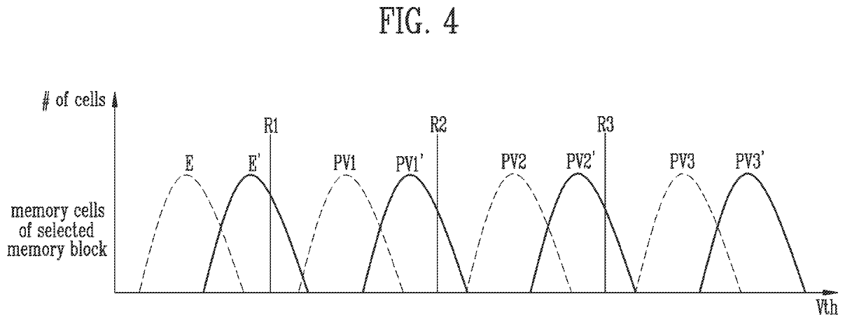

FIG. 4 is a diagram illustrating a threshold voltage distribution of memory cells included in a selected memory block, which is changed according to an erase operation on a shared memory block.

In FIG. 4, the horizontal axis of a graph represents threshold voltage Vth of memory cells, and the vertical axis of the graph represents number of memory cells (# of cells).

In FIG. 4, a case where one memory cell is programmed as a Multi-Level Cell (MLC) storing two-bit data will be described as an example. The embodiment of the present disclosure may be identically applied when one memory cell stores one-bit data or when one memory cell stores three-or-more-bit data.

Referring to FIG. 4, a threshold voltage distribution of memory cells included in a selected memory block may increase to a threshold voltage corresponding to any one state among an erase state E and first to third program states PV1 to PV3 through a program operation.

The memory device 100 may perform a read operation of acquiring data stored in memory cells by using read voltages for distinguishing program states from each other. First to third read voltages R1 to R3 may be voltages for distinguishing the erase state E and the first to third program states PV1 to PV3 from each other.

Meanwhile, the threshold voltage distribution of the memory cells included in the selected memory block may be changed based on a number of times an erase operation on a shared memory block is performed. When the erase operation on the shared memory block is performed, the threshold voltage distribution of the memory cells included in the selected memory block may be changed as unintended holes are introduced to or are leaked from the selected memory block. For example, referring to FIG. 3, when the selected memory block is the first memory block BLK1, the shared memory block may be the second memory block BLK2. In another example, when the selected memory block is the third memory block BLK3, the shared memory block may be the fourth memory block BLK4.

In an embodiment, when holes are introduced to the selected memory block, the threshold voltage distribution of the memory cells may be changed to a changed erase state E′ and changed first to third program states PV1′ to PV3′. That is, the threshold voltage distribution of the memory cells may be shifted to the right.

In another embodiment, when holes are leaked from the selected memory block, the threshold voltage distribution of the memory cells may be changed to a threshold voltage distribution lower than the erase state E and the first to third program states PV1 to PV3. That is, the threshold voltage distribution of the memory cells may be shifted to the left.

As the erase operation on the shared memory block is performed, data read from the selected memory block may include a large error bit number after the threshold voltage distribution of the memory cells included in the selected memory block is changed. That is, the read operation using the first to third read voltages R1 to R3 may fail. This may be referred to as a first page read fail.

However, after the first page read fail occurs, the data read from the selected memory block may include a relatively small error bit number. That is, a read operation performed after the first page read fail of the selected memory block may have a low probability that the read operation will fail. Accordingly, the memory device 100 may perform a dummy read operation on the selected memory block before the read operation on the selected memory block is performed so as to allow the first page read fail not to occur.

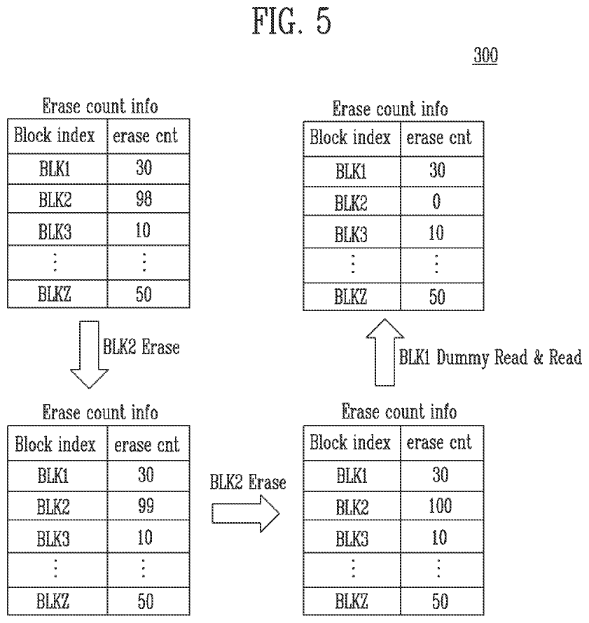

FIG. 5 is a diagram illustrating erase count information.

Referring to FIG. 5, the buffer memory 300 shown in FIG. 1 may store erase count information Erase count info. The erase count information Erase count info may include erase count values of the respective plurality of memory blocks. The erase count information Erase count info may include a memory block index Block index and an erase count value erase cnt.

In an embodiment, when a read request is received from the host, the memory system 50 may identify an erase count value of a shared memory block which shares a block word line with a selected memory block in which data corresponding to the read request is stored. For example, when the selected memory block is a first memory block BLK1, the memory system 50 may identify an erase count value of a second memory block BLK2 which shares a block word line with the first memory block BLK1. In an embodiment, the erase count value of the second memory block BLK2 may be 98.

The memory system 50 may determine whether a dummy read operation is to be performed, based on a result obtained by comparing the erase count value of the shared memory block with a reference count value. For example, when the reference count value is 100, the erase count value of the second memory block BLK2 is 98 which is smaller than the reference count value. Therefore, the memory system 50 may determine that a dummy read operation on the first memory block BLK1 will not be performed. After that, the memory system 50 may perform a read operation on the selected memory block.

In an embodiment, the memory system 50 may perform an erase operation on the shared memory block. The memory system 50 may perform the erase operation on the shared memory block and then update the erase count value of the shared memory block. For example, the memory system 50 may perform an erase operation on the second memory block BLK2 and then increase the erase count value of the second memory block BLK2 from 98 to 99.

After that, when a read request for requesting data stored in the selected memory block is received from the host, the memory system 50 may determine whether a dummy read operation is to be performed, based on the erase count value of the shared memory block. When the erase count value of the shared memory block is smaller than the reference count value, the memory system 50 might not perform the dummy read operation on the selected memory block. For example, because the erase count value of the second memory block BLK2 is 99, the memory system 50 may omit the dummy read operation on the first memory block BLK1, and perform the read operation on the first memory block BLK1.

When the erase operation on the shared memory block is performed, the memory system 50 may update the erase count value of the shared memory block. For example, the memory system 50 may perform the erase operation on the second memory block BLK2 and then increase the erase count value of the second memory block BLK2 from 99 to 100.

After that, when the read request for requesting the data stored in the selected memory block is received from the host, the memory system 50 may identify the erase count value of the shared memory block. When the erase count value of the shared memory block is equal to greater than the reference count value, the memory system 50 may perform the dummy read operation on the selected memory block and then perform the read operation on the selected memory block. For example, because the erase count value of the second memory block BLK2 is 100 when the reference count value is 100, the memory system 50 may perform the dummy read operation on the first memory block BLK1 and then the read operation on the first memory block BLK1.

The memory system 50 may perform the dummy read operation and the read operation on the selected memory block and then initialize the erase count value of the shared memory block. For example, the memory system 50 may perform the dummy read operation and the read operation on the first memory block BLK1 and then initialize the erase count value of the second memory block BLK2 to 0.

The memory system 50 may selectively perform the dummy read operation on the selected memory block, based on the erase count value of the shared memory block before the memory system 50 performs the read operation on the selected memory block in the read request of the host. The read operation performed after the dummy read operation on the selected memory block is performed may have a low probability that the read operation will fail. However, when the dummy read operation is performed whenever the read request of the host is received, a time required to provide the host with data read by the read operation may become long. Accordingly, the memory system 50 performs the dummy read operation on the selected memory block only when the probability that the read operation on the selected memory block will fail is high, based on the erase count value of the shared memory block, so that the time required to provide the host with the data read by the read operation can be reduced.

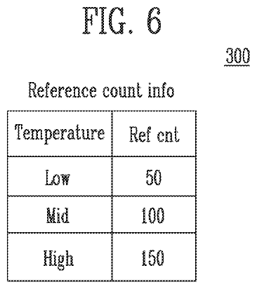

FIG. 6 is a diagram illustrating reference count information.

Referring to FIG. 6, the buffer memory 300 shown in FIG. 1 may store reference count information Reference count info. The reference count information Reference count info may include reference count values Ref cnt respectively corresponding to temperature information Temperature.

In an embodiment, a reference count value corresponding to low temperature information Low representing a low temperature may be 50. A reference count value corresponding to mid temperature information Mid representing a middle temperature may be 100. A reference count value corresponding to high temperature information High representing a high temperature may be 150. For example, the middle temperature may mean a room temperature. The room temperature may mean 15° C. to 25° C. The low temperature means a temperature lower than the room temperature. The high temperature may mean a temperature higher than the room temperature. The reference count value may have a smaller value as the temperature of the memory system becomes lower. The reference count value may have a larger value as the temperature of the memory system becomes higher.

In an embodiment, the memory controller may receive, from the temperature sensor, temperature information corresponding to any one of the low, mid, and high temperature information. The memory controller may determine a reference count value, based on the received temperature information.

In an embodiment, data read by a read operation may include a larger fail bit number as the temperature of the memory system becomes lower. That is, the necessity that a dummy read operation on a selected memory block is to be performed may be larger as the temperature of the memory system becomes lower. The memory system may determine whether the dummy read operation is to be performed by comparing the reference count value having a smaller value as the temperature of the memory system becomes lower with an erase count value of a shared memory block.

In an embodiment, the data read by the read operation may include a smaller fail bit number as the temperature of the memory system becomes higher. The necessity that the dummy read operation on the selected memory block is to be performed may be lower as the temperature of the memory system becomes higher. The memory system may determine whether the dummy read operation is to be performed by comparing the reference count value having a larger value as the temperature of the memory system becomes higher with the erase count value of the shared memory block.

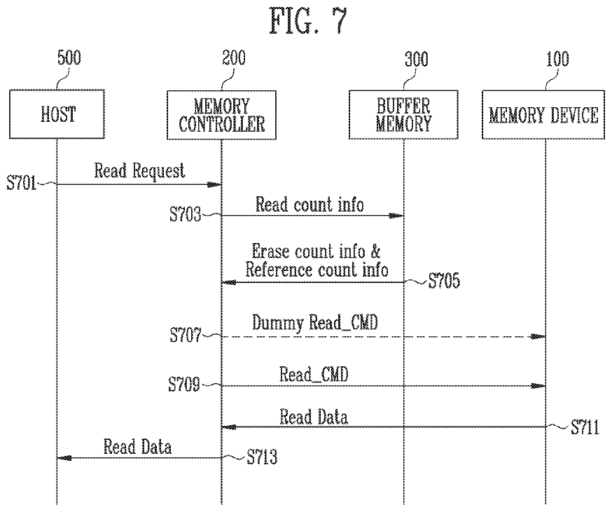

FIG. 7 is a diagram illustrating a dummy read operation and a read operation of the memory system according to a read request of the host.

Referring to FIG. 7, in S710, the memory controller 200 may receive a read request Read Request from the host 500. Data corresponding to the read request Read Request may be stored in a selected memory block.

In S703, the memory controller 200 may instruct the buffer memory 300 to read a count value count info. The count value count info may include an erase count value of a shared memory block which shares a block word line with the selected memory block and a reference count value. The reference count value may be determined based on temperature information received from the temperature sensor.

In S705, the memory controller 200 may acquire, from the buffer memory 300, an erase count value Erase count info of the shared memory block and a reference count value Reference count info corresponding to any one temperature information among low, mid, and high temperature information. The memory controller 200 may determine whether a dummy read operation on the selected memory block is to be performed, based on a result obtained by comparing the erase count value Erase count info of the shared memory block and the reference count value Reference count info.

In S707, the memory controller 200 may provide the memory device 100 with a dummy read command Dummy Read_CMD instructing the memory device 100 to perform the dummy read operation on the selected memory block when the erase count value Erase count info of the shared memory block is equal to or greater than the reference count value Reference count info. The memory controller 200 might not provide the dummy read command Dummy Read_CMD to the memory device 100 when the erase count value Erase count info of the shared memory block is smaller than the reference count value Reference count info.

In S709, the memory controller 200 may provide the memory device 100 with a read command Read_CMD instructing the memory device 100 to perform a read operation on the selected memory block.

In S711, the memory controller 200 may receive data Read Data read by the read operation from the memory device 100.

In S713, the memory controller 200 may provide the read data Read DATA to the host 500.

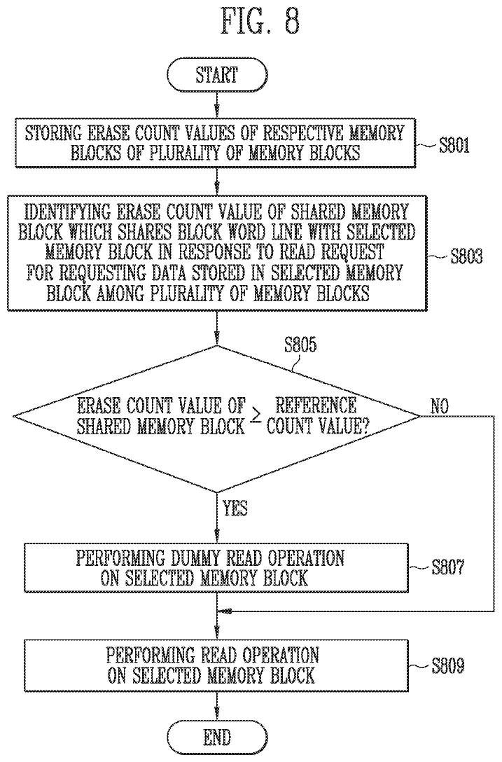

FIG. 8 is a flowchart illustrating an operation of the memory system in accordance with an embodiment of the present disclosure.

Referring to FIG. 8, in step S801, the memory system 50 may store erase count values of respective memory blocks of a plurality of memory blocks. The erase count values may be updated based on a number of times an erase operation on each of the plurality of memory blocks is performed.

In step S803, the memory system 50 may identify an erase count value of a shared memory block which shares a block word line with a selected memory block in response to a read request for requesting data stored in the selected memory block among the plurality of memory blocks.

In step S805, the memory system 50 may compare whether the erase count value of the shared memory block is greater than a reference count value. When the erase count value of the shared memory block is equal to or greater than the reference count value, step S807 may be performed. Alternatively, when the erase count value of the shared memory block is smaller than the reference count value, step S809 may be performed. When the erase count value of the shared memory block is smaller than the reference count value, the memory system 50 may skip performance of a dummy read operation on the selected memory block.

In the step S807, when the erase count value of the shared memory block is equal to or greater than the reference count value, the memory system 50 may perform the dummy read operation on the selected memory block.

In the step S809, the memory system 50 may perform a read operation on the selected memory block.

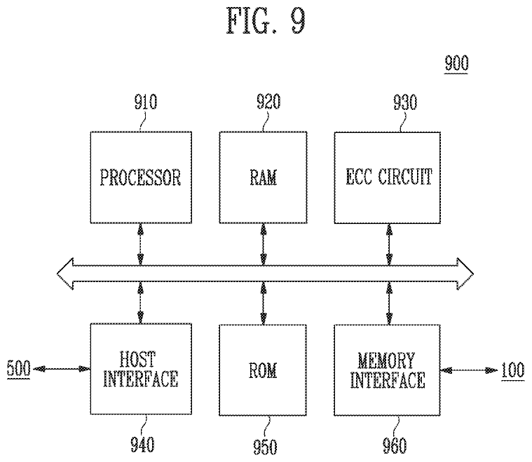

FIG. 9 is a diagram illustrating the memory controller shown in FIG. 1.

Referring to FIG. 9, the memory controller 900 may include a processor 910, RAM 920, an Error Correction Code (ECC) circuit 930, a host interface 940, ROM 950, and a memory interface 960.

The processor 910 may control a general operation of the memory controller 900. The processor 910 may control an operation of the memory controller 900 to store data requested from the host 500 in the memory device 100. In an embodiment, the processor 910 may include the operation controller 220 shown in FIG. 1. The processor 910 may determine whether a dummy read operation on a selected memory block is to be performed, based on a result obtained by comparing an erase count value of a shared memory block with a reference count value before a read operation of the selected memory block.

The RAM 920 may be used as a buffer memory, a cache memory, a working memory, or the like of the memory controller 900. In an embodiment, the RAM 920 may include erase count information and reference count information.

The ECC circuit 930 may perform error correction. The ECC circuit 930 may perform ECC encoding, based on data to be written in the memory device 100 through the memory interface 960. The ECC-encoded data may be transferred to the memory device 100 through the memory interface 960. The ECC circuit 930 may perform ECC decoding on data received from the memory device 100 through the memory interface 960.

The ROM 950 may store, in a firmware form, various information required when the memory controller 900 is operated.

The memory controller 900 may communicate with an external device (e.g., the host 500, an application processor, or the like) through the host interface 940. The memory controller 900 may receive data provided through the host interface 940. In an embodiment, the host interface 940 may receive a read request from the host 500. The host interface 210 shown in FIG. 1 may be implemented identically to the host interface 940 shown in FIG. 9.

The memory controller 900 may communicate with the memory device 100 through the memory interface 960. The memory controller 900 may transmit a command, an address, data, and the like to the memory device 100 through the memory interface 960. In an embodiment, the operation controller 220 shown in FIG. 1 may include the memory interface 960. The memory interface 960 may provide the memory device 100 with a dummy read command and a read command.

In accordance with the present disclosure, a memory system including a memory controller and a memory device can reduce a time required to provide a host with data stored in the memory device.

While the present disclosure has been shown and described with reference to certain embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described embodiments but should be determined by not only the appended claims but also the equivalents thereof.

In the above-described embodiments, all steps may be selectively performed or some of the steps may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A memory system comprising:
a memory device including a plurality of memory blocks; and
a memory controller configured to, when a read request for data stored in a first memory block among the plurality of memory blocks is received, determine whether a dummy read operation on the first memory block is to be performed, based on an erase count value of a second memory block which shares a block word line with the first memory block before a read operation on the first memory block is performed.

2. The memory system of claim 1, wherein the memory controller is configured to determine whether the dummy read operation is to be performed, based on a result obtained by comparing the erase count value of the second memory block with a reference count value.

3. The memory system of claim 2, wherein the memory controller is configured to control, when the erase count value of the second memory block is equal to or greater than the reference count value, the memory device to perform the dummy read operation on the first memory block and then perform the read operation.

4. The memory system of claim 2, wherein the memory controller is configured to control, when the erase count value of the second memory block is smaller than the reference count value, the memory device not to perform the dummy read operation but perform the read operation on the first memory block.

5. The memory system of claim 1, wherein the memory controller is configured to update the erase count values, based on a number of times an erase operation on the plurality of memory blocks is performed.

6. The memory system of claim 1, wherein the memory controller is configured to perform the dummy read operation on the first memory block and then initialize the erase count value of the second memory block.

7. The memory system of claim 2, wherein the memory controller is configured to determine the reference count value based on a temperature of the memory system.

8. The memory system of claim 7, wherein the memory controller is configured to determine a smaller value as the reference count value as the temperature of the memory system becomes lower.

9. The memory system of claim 1, wherein the memory device includes:
a first switch circuit connecting a first global word line group to a first local word line group of the first memory block; and
a second switch circuit connecting a second global word line group to a second local word line group of the second memory block.

10. The memory system of claim 9, wherein the first switch circuit and the second switch circuit are commonly connected to the block word line.

11. A method of operating a memory system, the method comprising:
storing erase count values of respective memory blocks of a plurality of memory blocks;
identifying an erase count value of a second memory block which shares a block word line with a first memory block among the plurality of memory blocks in response to a read request of a host with respect to data stored in the first memory block;
determining whether a dummy read operation on the first memory block is to be performed, based on the erase count value of the second memory block; and
performing a read operation on the first memory block.

12. The method of claim 11, wherein, in the determining of whether the dummy read operation on the first memory block is to be performed, the dummy read operation on the first memory block is performed when the erase count value of the second memory block is equal to or greater than a reference count value.

13. The method of claim 11, wherein, in the determining of whether the dummy read operation on the first memory block is to be performed, the performance of the dummy read operation is skipped when the erase count value of the second memory block is smaller than the reference count value.

14. The method of claim 11, wherein the erase count values are updated based on a number of times an erase operation on the plurality of memory blocks is performed.

15. The method of claim 11, wherein the erase count value of the second memory block is initialized after the dummy read operation on the first memory block is performed.

16. The method of claim 12, wherein the reference count value has a larger value as a temperature of the memory system becomes higher.

17. The method of claim 11, wherein a first local word line group connected to the first memory block and a second local word line group connected to the second memory block are electrically connected to different global word line groups through a block word line.

18. A memory controller comprising:
a host interface configured to receive a read request for requesting data stored in a selected memory block among a plurality of memory blocks; and
an operation controller configured to identify an erase count value of a shared memory block which shares a block word line with the selected memory block among erase count values corresponding to the respective memory blocks of a plurality of memory blocks in response to the read request, and selectively perform a dummy read operation on the selected memory block, based on the erase count value of the shared memory block and then read the data stored in the selected memory block.

19. The memory controller of claim 18, wherein, when the erase count value of the shared memory block is equal to or greater than a reference count value, the operation controller performs the dummy read operation on the selected memory block and then reads the data stored in the selected memory block.

20. The memory controller of claim 18, wherein, when the erase count value of the shared memory block is smaller than a reference count value, the operation controller does not perform the dummy read operation on the selected memory block but reads the data stored in the selected memory block.
